(19) United States
(12) Patent Application Publication
(10) Pub. No.: US 2026/0231572 A1
(43) Pub. Date: Aug. 6, 2026

(54) MICRO-LED AND MICRO-LED CHIP

(71) Applicant: Hue Inc., Shanghai (CN)

(72) Inventor: Feng Feng, Shanghai (CN)

(73) Assignee: Hue Inc., Shanghai (CN)

(21) Appl. No.: 19/458,937

(22) Filed: Jan. 26, 2026

(30) Foreign Application Priority Data
Jan. 26, 2025 (CN) 202510124084.8

(51) Int. Cl. H10H 20/841

(52) U.S. Cl. CPC H10H 20/841

(57) ABSTRACT

The present disclosure provides a micro-LED, including: a light-emitting mesa configured to emit light; and a reflective mirror layer configured to reflect light from the light-emitting mesa, wherein a side of the reflective mirror layer facing the light-emitting mesa has an atomic layer deposition layer, and the atomic layer deposition layer is configured to block metal diffusion in the reflective mirror layer. Through the present disclosure, metal diffusion and oxidation in the reflective mirror layer can be effectively suppressed.

### CROSS-REFERENCE TO RELATED APPLICATION

This application claims the priority benefit of China application serial no. 202510124084.8, filed on January 26, 2025. The entirety of the above-mentioned patent application is hereby incorporated by reference herein and made a part of this specification.

### BACKGROUND

### Technical Field

The present disclosure generally relates to the field of semiconductor, and more specifically relates to a Micro light-emitting diode (micro-LED). Furthermore, the present disclosure also relates to a micro-LED chip.

### Description of Related Art

Micro-LED is a new type LED structure obtained by thin-filming, miniaturizing, and arraying the original LED structure, which integrates the arrayed micro level micro-LEDs on an active addressing drive panel to achieve the lighting and individual control of the micro-LEDs, thereby outputting the desired display image. The core structure of the micro-LED is a PN junction diode composed of direct-bandgap semiconductor material. When the upper and lower electrodes apply a forward bias voltage to the micro-LED to allow current to pass through, electrons and holes recombine in the active area, and meanwhile emit monochromatic light photons.

The reflective mirror layer in an LED is located below or around the chip. It is a special structural layer, and its main function is to reflect photons, which avoids absorption or loss of light in the micro-LED chip, thereby improving the light extraction efficiency.

The reflective mirror layer is typically composed of metallic materials. Common materials include aluminum (Al) and silver (Ag), etc. These metals have the characteristic of high reflectivity and can effectively reflect light. For example, aluminum has high reflectivity in the visible light band, and cost is relatively low, and it is easy to process, so that it is widely used in many micro-LED products. The reflectivity of silver is even higher than the reflectivity of aluminum in some bands, but silver is prone to oxidation and diffusion, so special protective treatment is needed, otherwise, if silver oxidizes, its reflectivity will decrease, and the performance of the reflective mirror layer is affected, or if silver diffuses into other semiconductor structures, it is easy to cause short circuits or affect its performance.

Currently, there is a need for a reflective mirror structure in micro-LED chips that can suppress metal diffusion and oxidation.

### SUMMARY

One aspect of the present disclosure provides a micro-LED and a micro-LED chip, through the micro-LED and the micro-LED chip, metal diffusion and oxidation in the reflective mirror layer can be effectively suppressed.

In a first aspect of the present disclosure, the aforementioned task is achieved by a micro-LED, which includes:

a light-emitting mesa configured to emit light; and

a reflective mirror layer configured to reflect the light from the light-emitting mesa, where a side of the reflective mirror layer facing the light-emitting mesa has an atomic layer deposition layer, and the atomic layer deposition layer is configured to block metal diffusion in the reflective mirror layer.

In one embodiment of the present disclosure, an upper surface of the light-emitting mesa is greater than a lower surface of the light-emitting mesa, and the reflective mirror layer includes:

a side reflective mirror layer covering at least a part of side surface of the light-emitting mesa, and a side of the side reflective mirror layer facing the light-emitting mesa has an inclined surface to reflect the light from the light-emitting mesa upward; and

a bottom reflective mirror layer covering at least a part of a bottom surface of the light-emitting mesa, where a side of the bottom reflective mirror layer facing the light-emitting mesa has an atomic layer deposition layer.

In another embodiment of the present disclosure, an upper surface of the light-emitting mesa is less than a lower surface of the light-emitting mesa, and the reflective mirror layer covers a bottom surface of the light-emitting mesa.

In another embodiment of the present disclosure, the reflective mirror layer includes, starting from a side facing the light-emitting mesa:

an atomic layer deposition layer, a material of the atomic layer deposition layer is selected from one or more of the following items: nickel, platinum, titanium, and tantalum;

a reflective metal layer, the material of the reflective metal layer is selected from one or more of the following items: silver, aluminum, and gold;

a first barrier layer including at least a first barrier sublayer and a second barrier sublayer, where the materials of the first barrier sublayer and the second barrier sublayer are respectively selected from one or more of the following items: platinum, titanium, and tantalum; and

a second barrier layer, its material is selected from one or more of the following items: platinum, titanium, and tantalum.

In another embodiment of the present disclosure, the material of the second barrier layer is different from the material of the first barrier sublayer.

In another embodiment of the present disclosure, it is provided that:

the material of the atomic layer deposition layer is nickel;

the material of the reflective metal layer is silver;

the materials of the first barrier sublayer and the second barrier sublayer are titanium and platinum, respectively; and

the material of the second barrier layer is titanium.

In another embodiment of the present disclosure, it is provided that:

a thickness of the atomic layer deposition layer is 3 to 8 angstroms;

a thickness of the reflective metal layer is 800 to 1200 angstroms;

a thickness of the first barrier sublayer is 100 to 300 angstroms, and a thickness of the second barrier sublayer is 400 to 600 angstroms; and

a thickness of the second barrier layer is 100 to 300 angstroms.

In another embodiment of the present disclosure, the reflective mirror layer includes N first barrier sublayers and N second barrier sublayers arranged alternately with each other, where N is an integer and N = 2 to 5.

In another embodiment of the present disclosure, the micro-LED further includes:

an insulating layer including a recess, at least a part of the light-emitting mesa is arranged within the recess.

In another embodiment of the present disclosure, the micro-LED further includes:

a passivation layer arranged between the reflective mirror layer and the insulating layer.

In another embodiment of the present disclosure, the light-emitting mesa includes:

a first epitaxial layer extending beyond the recess of the insulating layer;

a second epitaxial layer located in the recess and in electrical contact with a first through-hole contact portion;

a light-emitting layer located in the recess and between the first epitaxial layer and the second epitaxial layer, and in electrical contact with the first epitaxial layer and the second epitaxial layer.

In another embodiment of the present disclosure, the material of the passivation layer is selected from one or more of the following items:

aluminum oxide, silicon oxide, and silicon nitride.

In another embodiment of the present disclosure, the micro-LED further includes:

a through-hole contact portion located at a bottom of the epitaxial layer to electrically connect the epitaxial layer with a drive circuit; and

an etch buffer layer located between the reflective mirror layer and the through-hole contact portion to prevent the through-hole contact portion from being over-etched.

In another embodiment of the present disclosure, the micro-LED further includes:

a bottom transparent conductive layer located between the reflective mirror layer and the through-hole contact portion to electrically connect the light-emitting mesa with the through-hole contact portion.

In a second aspect of the present disclosure, the aforementioned task is solved by a micro-LED chip, which includes:

a plurality of micro-LEDs according to the present disclosure, where the light-emitting mesa comprises a first epitaxial layer, a light-emitting layer, and a second epitaxial layer deposited in sequence, and each micro-LED further comprises:

a first electrode;

a passivation layer located between the side reflective mirror layer and the insulating layer;

a top transparent conductive layer arranged on the first epitaxial layer and in electrical contact with the first epitaxial layer; and

a second electrode arranged on a surface of the top transparent conductive layer; and

a drive circuit provided with a metal layer on its surface, the drive circuit is provided with a plurality of through-hole contact portions, and the plurality of through-hole contact portions are electrically connected with the metal layer, and the micro-LED is connected (for example, bonded) to the drive circuit through a bottom conductive bonding layer, and each light-emitting mesa corresponds to one of the plurality of through-hole contact portions.

In one embodiment of the present disclosure, the second electrode is a ring-shaped reflective electrode arranged around the light-emitting mesa.

In another embodiment of the present disclosure, the polarity of the second electrode is opposite to the polarity of the first electrode.

In another embodiment of the present disclosure, the material of the second epitaxial layer is a material layer of a second conductivity type including at least two or more elements of Ga, N, As, Al, In, and P, and the first epitaxial layer is a material layer of a first conductivity type including at least two or more elements of Ga, N, As, Al, In, and P, where the first conductivity type is different from the second conductivity type.

In another embodiment of the present disclosure, the light-emitting layer includes a multi-quantum-well layer, where the multi-quantum-well layer is an InGaN/GaN multi-quantum-well layer, an InGaN/AlGaN multi-quantum-well layer, an InGaAs/AlGaAs multi-quantum-well layer, or an AlGaInP multi-quantum-well layer.

In another embodiment of the present disclosure, a first side of the light-emitting layer has an electron barrier layer, and the first side is a side along which electrons migrate out of the light-emitting layer.

In another embodiment of the present disclosure, the material of the metal layer is an alloy of one or more of the following metals: Ni, Al, Ti, Ni, Pt, Au.

In another embodiment of the present disclosure, the material of the passivation layer is a Si₃N₄ film, a SiO₂ film, or an Al₂O₃ film.

In another embodiment of the present disclosure, the micro-LED chip further includes a microlens, where the microlens includes:

a lens portion located at an outermost side; and

a spacer portion located between the lens portion and the light-emitting mesa.

In a third aspect of the present disclosure, the aforementioned task is solved by a micro-LED chip, the micro-LED chip includes:

an upper stacked layer, which includes:

a light-emitting mesa configured to emit light, where a top surface area of the light-emitting mesa is greater than a bottom surface area of the light-emitting mesa;

a first insulating layer configured to accommodate a light-emitting mesa;

a reflective mirror layer, where the reflective mirror layer covers at least a part of a side surface and/or at least a part of the bottom surface of the light-emitting mesa, and has an atomic layer deposition layer on a side facing the light-emitting mesa, and the atomic layer deposition layer is configured to block metal diffusion in the reflective mirror layer; and

a first through-hole contact portion electrically connected with the bottom surface of the light-emitting mesa and passing through the first insulating layer, where the first insulating layer further accommodates the first through-hole contact portion; and

a lower stacked layer, which comprises:

a second insulating layer; and

a second through-hole contact portion passing through the second insulating layer; and

a drive backplane electrically connected with the second through-hole contact portion, where the lower stacked layer is bonded with the upper stacked layer through hybrid bonding, such that the first through-hole contact portion is bonded with the second through-hole contact portion and the first insulating layer is bonded with the second insulating layer.

The present disclosure has at least the following technical effects:

(1) By adding an atomic layer deposition layer made of a barrier metal on the side of the reflective mirror layer facing the light-emitting mesa, the metal in the reflective mirror layer can thus be effectively prevented from diffusing into the light-emitting mesa through the bottom transparent conductive layer arranged between the reflective mirror layer and the light-emitting mesa and causing performance degradation or failure of the light-emitting mesa, and it suppresses the oxidation of the reflective metal, thereby suppressing the decrease in reflection efficiency caused by oxidation;

(2) In the present disclosure, the metal barrier effect is significantly improved by changing the number of alternating metal layers (e.g., alternating layers of platinum and titanium) in the reflective mirror layer; furthermore, second and third barrier layers made of barrier metals are also arranged on the side of the reflective mirror layer facing away from the light-emitting mesa, and diffusion of easily diffusible metals such as silver from the reflective mirror layer into the insulating layer is effectively suppressed, so that short circuits or failures of the insulating layer caused by diffusion are avoided.

(3) In the present disclosure, by protruding the first epitaxial layer at the upper surface of the light-emitting mesa beyond the recess of the insulating layer, the surface area of the first epitaxial layer is not limited by the aperture of the recess, so as to significantly increase the surface area and thickness of the first epitaxial layer; furthermore, due to the fact that only the light-emitting layer and the second epitaxial layer need to be accommodated inside the recess, these two layers have a greater area and thickness compared to the structure that requires accommodating three layers in the prior art, so that the area and thickness of the epitaxial layer are better increased and the light output is increased.

### BRIEF DESCRIPTION OF THE DRAWINGS

The present disclosure is further explained below with reference to the accompanying drawings in conjunction with specific implementations.

FIG. 1 shows a first embodiment of a reflective mirror layer according to the present disclosure.

FIG. 2 shows a second embodiment of a reflective mirror layer according to the present disclosure.

FIG. 3 shows a first application scenario of a reflective mirror layer according to the present disclosure.

FIG. 4 shows a second application scenario of a reflective mirror layer according to the present disclosure.

### DESCRIPTION OF THE EMBODIMENTS

In the following description, the present disclosure is described with reference to various embodiments. However, those skilled in the art will recognize that various embodiments can be implemented without one or more specific details or with other alternative and/or additional methods, materials, or components. In other situations, well-known structures, materials, or operations are not shown or described in detail so as not to obscure the inventive point of the present disclosure. Similarly, for the purpose of explanation, specific quantities, materials, and configurations are set forth in order to provide a comprehensive understanding of embodiments of the present disclosure. However, the present disclosure is not limited to these particular details.

It should be noted that various components in the accompanying drawings may be exaggerated for the purpose of illustrative illustration and are not necessarily true to scale. In the accompanying drawings, components that are identical or functionally identical are provided with the same accompanying drawing reference signs.

In the present disclosure, unless otherwise specified, the words “arranged on”, “arranged above” and “arranged over” do not exclude the existence of intermediates between the two. Furthermore, “arranged on or above” merely indicates the relative positional relationship between the two components, but under certain circumstances, such as when the product direction is reversed, it can be converted to “arranged under or below”, and vice versa.

In the present disclosure, the embodiments are merely intended to illustrate the scheme of the present disclosure and should not be construed as limiting.

In the present disclosure, the quantifiers “a” and “one” do not exclude scenarios with a plurality of elements, unless otherwise specified.

In the present disclosure, the term “connect” may refer to either the two being directly connected or the two being indirectly connected through an intermediate component.

In the present disclosure, the term “configure” refers to the setting of the shape, structure, material, and/or function of a target object to achieve a desired technical effect, “configure” includes various alternative technical means to achieve this technical effect, and these technical means become apparent under the teachings of the present disclosure.

In the present description, a reference to “an embodiment” or “the embodiment” means that particular feature, structure or characteristic described in connection with the embodiment are included in at least one embodiment of the present disclosure. The phrase “in one embodiment” appearing throughout this description may not necessarily all refer to the same embodiment.

It should be noted that the embodiments of the present disclosure describe the process steps in a specific order, however, this is only for the purpose of illustrating the specific embodiment, rather than limiting the order of the steps. On the contrary, in different embodiments of the present disclosure, the order of the steps can be modified according to the adjustment of the process.

In the present disclosure, the term “upper portion of the light-emitting mesa” refers to the portion of the light-emitting mesa facing the microlens or light extraction side, while the term “lower portion of the light-emitting mesa” refers to the portion of the light-emitting mesa facing the drive backplane or anode. Similarly, the term “upper surface or top surface of the light-emitting mesa” refers to the surface of the light-emitting mesa facing the microlens or light extraction side, while the term “lower surface or bottom surface of the light-emitting mesa” refers to the surface of the light-emitting mesa facing the drive backplane or anode.

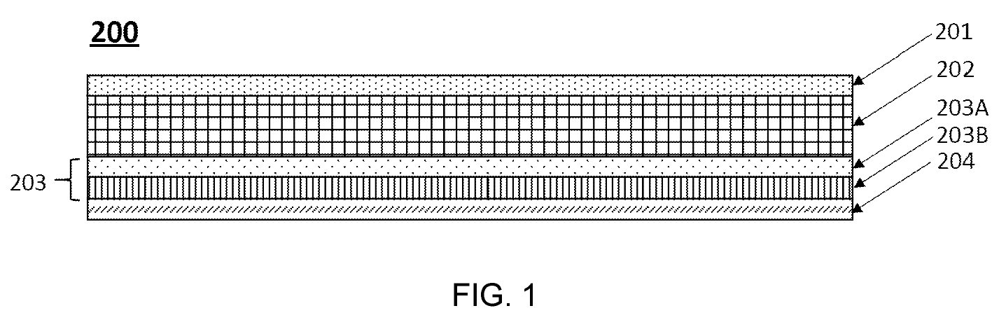

FIG. 1 illustrates a first embodiment of a reflective mirror layer 200 according to the present disclosure.

As shown in FIG. 1, the reflective mirror layer 200 according to the present disclosure includes, from top to bottom, an atomic layer deposition layer 201, a reflective metal layer 202, a first barrier layer 203, and a second barrier layer 204, and the upper side of the reflective mirror layer 200 faces the light-emitting mesa or epitaxial layer of the micro-LED, and the lower side of the reflective mirror layer 200 faces away from the light-emitting mesa or epitaxial layer of the micro-LED or faces the bottom transparent conductive layer. Each layer is described below, respectively.

The atomic layer deposition layer 201, which is arranged at the uppermost layer, i.e., the outermost side facing the light-emitting mesa or epitaxial layer. The material of the atomic layer deposition layer 201 may include, for example, nickel, platinum, titanium, and tantalum. The preferred material for atomic layer deposition layer 201 is nickel. The thickness of the atomic layer deposition layer is 3 to 8 angstroms, preferably 5 angstroms. 1 angstrom = 10^(-10) meters. The function of the atomic layer deposition layer 201 is to deposit a barrier metal (e.g., nickel) of a certain thickness on the outer side of the reflective metal layer 202 through an atomic layer deposition (ALD) process, and the barrier metal can effectively block or at least suppress outward diffusion of the reflective metal layer 202, such as prevent its diffusion through the transparent conductive layer into the light-emitting mesa or epitaxial layer arranged thereon.

Reflective metal layer 202, which is arranged between the atomic layer deposition layer 201 and the first barrier layer 203, and which is configured to reflect light, and the materials of the reflective metal layer 202 may include, for example, silver, aluminum, and gold.

Aluminum (Al): Aluminum is a commonly used optical reflective material. It has high reflectivity, reaching approximately 80%-90% in the visible light range. Moreover, aluminum has a relatively low cost and is easy to form various shapes of reflective mirrors. Aluminum also has a certain reflective capability in the ultraviolet and infrared ranges, but its reflective performance will change with the variation of wavelength.

Silver (Ag): The reflectivity of silver is higher than that of aluminum in the visible light band, reaching over 95%, particularly in the blue and green light bands, its reflective performance is more outstanding. However, silver is easily oxidized, and the reflectivity of oxidized silver will decrease. Furthermore, silver is prone to diffusion. Considering that silver is prone to diffusion and oxidation, the inventor has found that, by arranging an atomic layer deposition layer 201 before the silver layer, the diffusion and oxidation of the reflective metal layer made of silver can be effectively prevented.

Gold (Au): Gold has excellent reflective performance in the infrared band, and its reflectivity can reach over 98% in the infrared region. However, the reflectivity of gold in the visible light band is relatively low, and its color is golden yellow, therefore, gold is mainly used for the light reflection of infrared micro-LEDs.

The material of the reflective metal layer 202 is preferably a high-reflectivity metal, such as silver. The thickness of the reflective metal layer may be, for example, 800 to 1200 angstroms, preferably 1000 angstroms.

The principle of metal reflection of light is as follows: when light is incident on the surface of a metal, free electrons in the metal will perform forced vibration under the action of the electric field of light, and these vibrating electrons will radiate electromagnetic waves with the same frequency as the incident light, which is the source of reflected light.

The penetration depth of light in a metal (also known as the skin depth) is a physical quantity that is related to the properties of the metal material and the frequency of light. It represents the distance that light penetrates when its intensity decays to 1/e (approximately 37%) of the surface intensity. For metals, the depth of light penetration is usually at the nanometer level. That is to say, light can penetrate metal surfaces to a certain depth at the nanometer level (such as 200 nanometers).

In view of this, the atomic layer deposition layer 201 is constructed to be as thin as possible, e.g., not exceeding 10 angstroms, such as 3 to 8 angstroms, preferably 5 angstroms, so that light from the light-emitting mesa can penetrate the atomic layer deposition layer 201 on the surface as unobstructed as possible and be reflected by the reflective metal layer 202 with high reflectivity arranged behind it. However, on the other hand, if the atomic layer deposition layer 201 is too thin, it will also affect its metal barrier function, therefore, the inventor uniquely configures its layer thickness to be 3 to 8 angstroms, preferably 5 angstroms, to achieve both good metal barrier and high reflectivity of the reflective metal layer 202.

The first barrier layer 203, which is arranged between the reflective metal layer 202 and the second barrier layer 204, and includes at least a first barrier sublayer 203A and a second barrier sublayer 203B. The first barrier sublayer 203A and the second barrier sublayer 203B may, for example, include platinum, titanium, and tantalum, respectively. The thickness of the first barrier layer is 100 to 300 angstroms, preferably 200 angstroms, and the thickness of the second barrier layer is 400 to 600 angstroms, preferably 500 angstroms. For example, the first barrier layer 203A is preferably made of titanium, while the second barrier layer 203B is preferably made of platinum. Furthermore, the first barrier layer 203 may be repeated, for example, the reflective mirror layer 200 may include a plurality of first barrier layers 203 arranged successively with each other, such as 2, 3, 4, 5, or other numbers of first barrier layers 203. The first barrier layer 203 is configured to provide a metal barrier and prevent oxidation of the reflective metal layer 202 from the back, particularly, it can block metal atoms such as silver of the reflective metal layer from entering the insulating layer and affecting its insulation properties. Particularly when the first and second barrier sublayers 203A and 203B are titanium and platinum, respectively, the stacked layer of titanium and platinum has the following technical effects:

(1) The stacked layer of titanium and platinum can effectively prevent the reflective mirror layer material from being oxidized or corroded by chemical substances. In the reflective mirror layer, if the basic reflective material (such as silver) is oxidized, its reflectivity will significantly decrease. Titanium and platinum themselves have high chemical stability, which can prevent oxygen and other chemical substances that may cause deterioration of the reflective mirror layer material from contacting the core material of the reflective mirror layer, such as silver, thereby ensuring the reflective performance remains stable during long-term use.

(2) The stacked layer of titanium and platinum can adjust the optical constants of the reflective mirror layer to better adapt to different reflective metals. Different optical devices have different requirements for the optical parameters of the reflective mirror layer (such as refractive index, extinction coefficient, etc.). Titanium and platinum have specific optical properties in the optical frequency band, by adjusting the thickness and number of layers of the stacked layer, the optical characteristics of the reflective metal layer can be finely tuned to meet the needs of specific optical systems. Particularly when the number of stacked layers is 3, it has good reflection characteristics for the light of the light-emitting mesa of the micro-LED, meanwhile also has good metal blocking and oxidation resistance for the silver reflective metal layer.

The second barrier layer 204, which is arranged on the outermost side of the reflective mirror layer 200 facing the bottom transparent conductive layer. Materials of the second barrier layer 204 may include, for example, platinum, titanium, and tantalum, preferably titanium. The thickness of the second barrier layer may be, for example, 100 to 300 angstroms, preferably 200 angstroms. On one hand, the second barrier layer 204 has functions of metal barrier and anti-oxidation, on the other hand, it can prevent the oxidation of the reflective metal layer and block its metal diffusion, moreover it can participate in the fine-tuning of the reflective characteristics of the reflective metal layer, for example, it can form a titanium-platinum-titanium fine-tuning stacked layer with the first and second barrier sublayers of the first barrier layer 203, in this case, the material of the second barrier layer 204 is preferably the same as the material of the first barrier sublayer, for example, both are titanium.

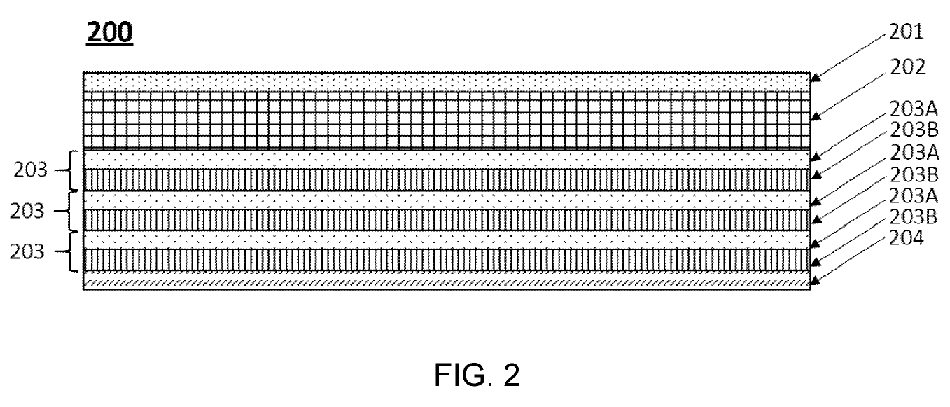

FIG. 2 illustrates a second embodiment of the reflective mirror layer 200 according to the disclosure.

The reflective mirror layer 200 of the second embodiment is substantially the same as the reflective mirror layer 200 of the first embodiment, and the main difference lies in, in the second embodiment, the material of the atomic layer deposition layer is nickel with a thickness of 5 angstroms, the material of the reflective metal layer is silver with a thickness of 1000 angstroms, the materials of the first and second barrier sublayers are titanium and platinum with thicknesses of 200 and 500 angstroms, respectively, and the material of the second barrier layer is titanium with a thickness of 200 angstroms; furthermore, the number of layers of the first barrier layer 203 is 3.

In the present embodiment, an atomic layer deposition layer 201 made of nickel is arranged on the front side of the reflective metal layer 202, and a first barrier layer 203 composed of three titanium layers and platinum layers is arranged after the reflective metal layer 202 made of silver, so that titanium and platinum alternate with each other, and the second barrier layer 204 made of titanium is arranged after the first barrier layer 203. In this way, the arrangement of three pairs of stacked layers can improve the functions of blocking and oxidation resistance for the silver reflective metal layer, and also fine tune the optical reflection characteristics of silver, furthermore, the second barrier layer and the first barrier layer 203 made of titanium form a titanium-platinum-titanium stacked layer pair, it further fine-tunes the reflection characteristics of silver.

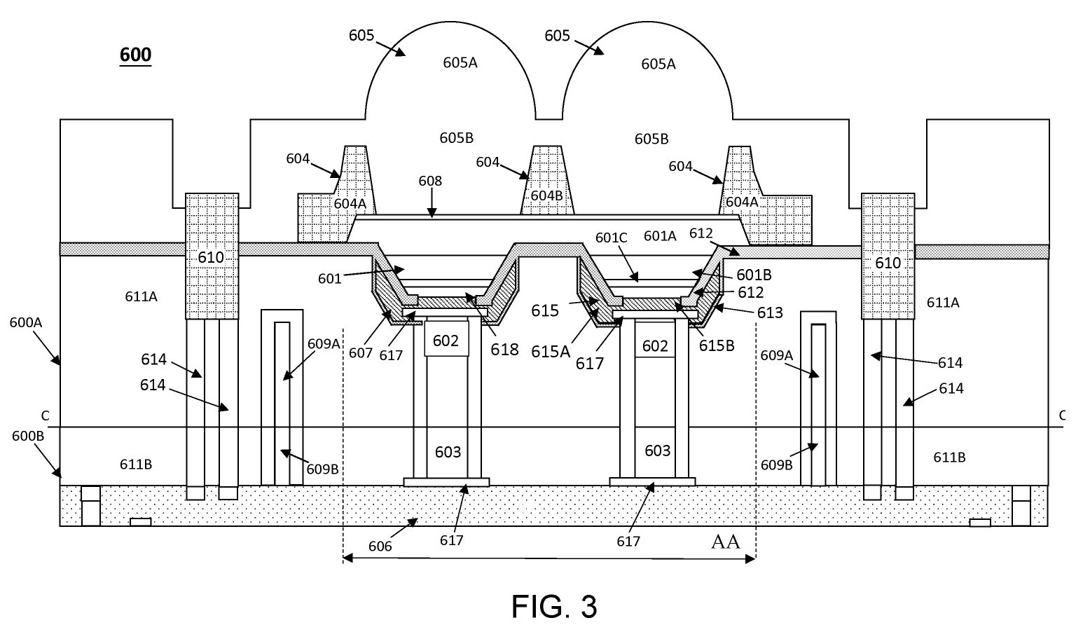

FIG. 3 illustrates a first application scenario of the reflective mirror layer 200 according to the present disclosure. In this application scenario, the light-emitting mesa or epitaxial layer of the micro-LED chip 600 has an upside-down arranged trapezoidal structure, i.e., its light-emitting mesa is a structure with a larger upper surface and a smaller lower surface, consequently, the reflective mirror layer 200 is arranged to surround all side surfaces of the light-emitting mesa in the insulating layer and cover its bottom surface, so that the light reflection area is maximized, and thus improving the luminous efficiency of the micro-LED is improved.

The various components of the micro-LED chip 600 are described in detail below.

As shown in FIG. 3, the micro-LED chip 600 according to the present disclosure includes an upper stacked layer 600A and a lower stacked layer 600B, the upper stacked layer 600A and the lower stacked layer 600B are formed into a complete micro-LED chip 600 through hybrid bonding at interface A. The structure and components of the upper stacked layer 600A and the lower stacked layer 600B are described in detail below.

The upper stacked layer 600A includes a first insulating layer 611A, a light-emitting mesa 601, a top transparent conductive layer 608, a first electrode 604 (cathode), a first through-hole contact portion 602, a second electrode 610 (anode), a first bonding mark 609A, and microlens 605. The various components are described below, respectively.

The first insulating layer 611A is configured to accommodate at least a part of the light-emitting mesa 601 and provide electrical insulation for it. Herein, the first insulating layer 611A has a recess 607 configured to accommodate the light-emitting layer and the second epitaxial layer of the light-emitting mesa 601, as well as the ancillary structures of the light-emitting mesa 601. For a detailed description of the light-emitting mesa 601 and its ancillary structures (such as the passivation layer 612, the reflective mirror layer 615, etc.), reference may be made to the light-emitting mesa 601 and description thereof. Herein, it should be noted that the recess 607 may be formed after the light-emitting mesa 601, i.e., the light-emitting mesa 601 and its ancillary structures are first formed on a temporary substrate, then the first insulating layer 611A surrounding them is formed on the light-emitting mesa and its ancillary structures. The material of the first insulating layer 611A may be, for example, silicon dioxide, silicon nitride, high-k dielectric materials (such as hafnium oxide, aluminum oxide, etc.), and so on. Methods for forming the first insulating layer 611A may include thermal oxidation, chemical vapor deposition (CVD), etc. The thickness of the first insulating layer 611A is, for example, 1 to 3 μm, preferably 2 μm, and more preferably 0.6 to 1.4 μm. Furthermore, the first insulating layer 611A may be planarized at interface A (e.g., through chemical mechanical polishing CMP) to facilitate hybrid bonding with the second insulating layer 611B.

The first insulating layer 611A is transparent to light emitted from the light-emitting mesa 601. In some embodiments, the first insulating layer 611A is made of a dielectric material such as solid inorganic material or plastic material. In some embodiments, the solid inorganic material includes silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof. In some embodiments, the plastic material includes polymers such as SU-8, PermiNex, or benzocyclobutene (BCB), or transparent plastics (resins) including spin-on glass (SOG), or adhesive micro resist BCL-1200, or any combination thereof. In some embodiments, the first insulating layer 611A may facilitate the passage of light emitted from the light-emitting mesa 601. In some embodiments, the first insulating layer 611A may include a plurality of portions, such as three embedded dielectric portions and two adhering dielectric portions. The embedded dielectric portions refer to the dielectric layers surrounding each light emitting diode structure; while the adhering dielectric portions refer to the dielectric layers between two light emitting diode structures. The embedded dielectric portions and the adhering dielectric portions may have the same or different compositions.

The light-emitting mesa 601 is configured to emit light, the top surface area of the light-emitting mesa 601 is greater than the bottom surface area of the light-emitting mesa 601, the light-emitting mesa 601 is in the shape of an upside-down arranged trapezoid. The inclination angle of the light-emitting mesa 601 may be, for example, 10° to 85°, preferably 30° to 70°, and particularly 35° to 50°. The light-emitting mesa 601 includes a first epitaxial layer 601A, a light-emitting layer 601B, and a second epitaxial layer 601C, the first epitaxial layer 601A is arranged on the top of the light-emitting mesa, i.e., the side facing the light extraction surface; the light-emitting layer 601B is arranged in the recess 607 and arranged between the first epitaxial layer 601A and the second epitaxial layer 601C; and the second epitaxial layer 601C is arranged on the bottom of the light-emitting mesa 601, i.e., the side facing the drive backplane 606. The light-emitting layer 601B may include, for example, a multi-quantum-well layer and an electron barrier layer. In one embodiment of the present disclosure, the first epitaxial layer 601A is an N-type GaN layer or an N-type AlGaN layer, and the second epitaxial layer 601C is a P-type GaN layer or a P-type AlGaN layer, i.e., the material of the second epitaxial layer is a material layer of a second conductivity type including at least two or more elements of Ga, N, As, Al, In, and P, and the first epitaxial layer is a material layer of a first conductivity type including at least two or more elements of Ga, N, As, Al, In, and P. The multi-quantum-well layer is an InGaN/GaN multi-quantum-well layer, an InGaN/AlGaN multi-quantum-well layer, or an InGaAs/AlGaAs multi-quantum-well layer. The electron barrier layer is arranged on the first side of the light-emitting layer, and the first side refers to the side along which electrons migrate out of the light-emitting layer. In yet another embodiment of the present disclosure, the first epitaxial layer may also be a P-type GaN layer or a P-type AlGaN layer, and the second epitaxial layer is an N-type GaN layer or an N-type AlGaN layer. The top width of the light-emitting mesa 601 is, for example, 0.5 to 3 μm, preferably 1.0 to 2.0 μm. The thickness of the first epitaxial layer 601A is, for example, 4000 to 5000 angstroms, the thickness of the light-emitting layer 601B is, for example, 3500 to 4000 angstroms, and the thickness of the second epitaxial layer 601C is, for example, 2500 to 3500 angstroms. 1 angstrom = 10^(-10) m. From FIG. 3, it can also be seen that the first epitaxial layer 601A is located outside the recess 607, while the light-emitting layer 601B and the second epitaxial layer 601C are located within the recess 607, therefore, the surface area of the first epitaxial layer 601A is not limited by the aperture area of the recess 607 but can be significantly greater than the aperture area of the recess 607, thereby significantly increasing the area and thickness of the first epitaxial layer 601A; furthermore, due to the fact that merely the light-emitting layer 601B and the second epitaxial layer 601C need to be accommodated in the recess 607, these two layers have a larger area and thickness compared to the structure that requires accommodating three layers in the prior art, and thus the area and thickness of the epitaxial layer 601 are better increased, and the light output is improved. It can also be seen herein that the first epitaxial layer 601A passes through the first electrode 604 (herein is the cathode) from below the first electrode 604, so that the first epitaxial layers 601A of adjacent light-emitting mesas 601 can be connected to each other, and thus in the case of a common-cathode structure (i.e., where the first epitaxial layers of all micro-LEDs in the same array are connected to a common cathode), compared to the case where it is connected to the cathode 604 solely by the top transparent conductive layer 608 covering it, the conductivity between the cathode 604 and the first epitaxial layer 601A can be significantly enhanced, thereby increasing its power supply. Furthermore, the contact cross-section between the first epitaxial layer 601A and the cathode 604 at the edge is partially planar and partially inclined surface. The inclined surface increases the contact area between the first epitaxial layer 601A and the cathode 604 compared to a vertical surface, and thus the conductivity is increased.

The light-emitting mesa 601 also includes ancillary structures such as passivation layers 612 and 613, a reflective mirror layer 615, and a bottom transparent conductive layer 618, etc. The passivation layer 612 is arranged between the light-emitting mesa 601 and the reflective mirror layer 615, and optionally extends on the upper surface of the first insulating layer 611A, and the passivation layer 613 is arranged between the inner wall of the recess 607 and the reflective mirror layer 615, and optionally extends on the upper surface of the first insulating layer 611A. In another embodiment, merely one of the passivation layers 612 and 613 extends on the upper surface of the first insulating layer 611A, or neither does not extend over the upper surface of the first insulating layer 611A, instead, they extend merely until the upper surface of the first insulating layer 611A, while the upper surface of the first insulating layer 611A is covered by another insulating layer or dielectric layer. The function of passivation layers 612 and 613 is not only to reduce current leakage at the sidewalls, but also to passivate sidewall defects and block damage to the light-emitting mesa caused by water, oxygen, etc., during operation, they can also prevent metal diffusion from the reflective mirror layer 615, the cathode 604 etc. to the first insulating layer 611 or the light-emitting mesa 601. The passivation layers 612 and 613 may be formed by depositing SiO₂ material using a CVD process, and also may be formed by depositing Al₂O₃ material using an ALD process. The bottom transparent conductive layer 618 is arranged between the second epitaxial layer 601C and the reflective mirror layer 615. The bottom transparent conductive layer 618 is configured to electrically connect the second epitaxial layer 601C of the light-emitting mesa 601 to the reflective mirror layer 615 and further to the through-hole contact portion 602. The material of the bottom transparent conductive layer 618 is, for example, metal oxide such as indium tin oxide ITO or zinc oxide ZnO, etc., its formation methods include, for example, physical vapor deposition (PVD), chemical vapor deposition (CVD), sol-gel method, solution coating method, etc.

The reflective mirror layer 615 is configured to reflect light from the light-emitting mesa 601 upward. For this purpose, the reflective mirror layer 615 has an inclined surface on the side facing the light-emitting mesa 601, the inclination angle of this surface is, for example, the same as the inclination angle of the light-emitting mesa, of 10° to 85°, preferably 30° to 70°, particularly 35° to 50°.

Herein, the reflective mirror layer 615 has a side reflective mirror layer 615A and a bottom reflective mirror layer 615B. The side reflective mirror layer 615A covers at least a part of the side surface of the light-emitting mesa 601. Both the side reflective mirror layer 615A and the bottom reflective mirror layer 615B are configured to reflect light from the light-emitting mesa 601 upward, while the bottom reflective mirror layer 615B is also configured to electrically connect the bottom transparent conductive layer 618 with the first through-hole contact portion 602. In the present embodiment, the side reflective mirror layer 615A covers the side surface of the part of the light-emitting mesa 601 within the recess 607, and the side reflective mirror layer 615A is formed between the passivation layer 612 and the inner wall of the recess 607 of the insulating layer. Due to the presence of the passivation layer 612, the side reflective mirror layer 615A may or may not have an atomic layer deposition layer on the side facing the light-emitting mesa 601. In the case of having an atomic layer deposition layer, it is possible to further prevent the metal in the reflective mirror layer 615 from penetrating into the light-emitting mesa 601 through the passivation layer 612. The side reflective mirror layer 615A has an inclined surface on the side facing the light-emitting mesa 601 to reflect light from the light-emitting mesa upward, and the inclination angle of the inclined surface is, for example, the same as the inclination angle of the light-emitting mesa 601, of 10° to 85°, preferably 30° to 70°, and especially 35° to 50°. The bottom reflective mirror layer 615B covers at least a part of the bottom surface of the light-emitting mesa 601. In the present embodiment, the bottom reflective mirror layer 615B covers the bottom transparent conductive layer 618 of the light-emitting mesa 601. The bottom reflective mirror layer 615B has an atomic layer deposition layer on the side facing the light-emitting mesa 601. The atomic layer deposition layer can block metal from the reflective metal layer to prevent its diffusion while substantially not affecting light reflection. For the specific structure of the reflective mirror layer 615, reference may be made to FIGS. 1 and 2 and their descriptions.

The reflective mirror layer 200 includes, from top to bottom (i.e., from the side facing the light-emitting mesa 601 to the side facing away from the light-emitting mesa 601) an atomic layer deposition layer 201, a reflective metal layer 202, a first barrier layer 203, and a second barrier layer 204, the upper side of the reflective mirror layer 200 faces the light-emitting mesa or epitaxial layer of the micro-LED, and the lower side of the reflective mirror layer 200 faces away from the light-emitting mesa or epitaxial layer of the micro-LED or faces the bottom transparent conductive layer.

For example, the stacked layer structure of the reflective mirror layer 615 is as follows (in an order from close to the light-emitting mesa to far away from the light-emitting mesa): Atomic layer deposition layer 201, the material of which is nickel, the thickness is 5 angstroms; Reflective metal layer 202, the material of which is silver, the thickness is 1000 angstroms; First and second barrier sublayers 203A and 203B, the materials are titanium and platinum, respectively, the thicknesses are 200 and 500 angstroms, respectively; Second barrier layer 204, the material of which is titanium, the thickness is 200 angstroms. Furthermore, the number of the first barrier layer 203 is 3.

The reflective mirror layer 615 can be formed, for example, through methods such as evaporation, sputtering, or chemical vapor deposition (CVD), etc., the atomic layer deposition layer 201 of the reflective mirror layer 615 is formed by atomic layer deposition. The thickness of the passivation layer 612 between the reflective mirror layer 615 and the light-emitting mesa 601 is 800 to 2000 angstroms, preferably 1000 to 1600 angstroms. The thickness of the passivation layer 613 between the reflective mirror layer 615 and the inner wall of the recess 607 is 200 to 800 angstroms, preferably 300 to 600 angstroms.

The top transparent conductive layer 608 is arranged on the first epitaxial layer 601A and electrically connects the first electrode 604 (cathode) with the first epitaxial layer 601A. Herein, the top transparent conductive layer 608 extends on the first epitaxial layer 601A and fully covers the first epitaxial layer 601A, thereby providing more uniform power supply for the first epitaxial layer 601A. In other embodiments, the top transparent conductive layer 608 may merely partially cover the first epitaxial layer 601A. Furthermore, the top transparent conductive layer 608 extends below the first electrode 604, which is the cathode in this case, such that the top transparent conductive layer 608 extends continuously on the first epitaxial layer 601A of adjacent light-emitting mesas 601, so that the coverage area for the first epitaxial layer 601A is increased. The material of the top transparent conductive layer 608 is, for example, metal oxide such as indium tin oxide ITO or zinc oxide ZnO, etc., its formation methods, for example, include physical vapor deposition (PVD), chemical vapor deposition (CVD), sol-gel method, solution coating method, etc.

The first electrode 604, herein is the cathode, and is arranged to surround the light-emitting mesa 601. The cathode 604 and its connecting components may be made of materials such as metals (such as copper, silver, or aluminum), graphene, ITO, aluminum doped zinc oxide (AZO) or fluorine doped tin oxide (FTO), or any combination of the above materials. In yet another embodiment of the present disclosure, the cathode 604 and its connecting components may be made of non-transparent or transparent conductive materials, such as indium tin oxide (ITO). In a preferred embodiment, the cathode 604 is made of a reflective metal (such as copper, silver or aluminum), so that the cathode 604 can optically isolate adjacent light-emitting mesas 601 from each other and meanwhile also can reflect light from the light-emitting mesas 601, for example, reflect the light upward to the microlens 605, thereby increasing light output. In another embodiment, a reflective layer, such as a silver layer, may be coated onto the surface of the cathode 604 to provide reflective capability. Herein, the surface of the cathode 604 facing the light-emitting mesa 601A is an inclined surface, and it is inclined toward two sides (i.e. inclined from the bottom surface toward two sides), so that the light falling on it can be reflected upward, i.e. toward the light extraction side. Furthermore, the cathode 604 may be divided into an edge cathode 604A and a central cathode 604B, the edge cathode 604A is arranged between the second electrode 610 (herein is the anode) and the outermost light-emitting mesa 601, a part of the edge cathode 604A is arranged on the passivation layer 612, and another portion is arranged on the top transparent conductive layer 608, while the central cathode 604B is arranged between adjacent light-emitting mesas 601, the central cathode 604B is arranged on the top transparent conductive layer 608. In this way, the edge cathode 604A can completely cover the side surface of the first epitaxial layer 601A and be in electrical contact with it, thereby increasing the electrical contact area between the cathode 604 and the first epitaxial layer 601A.

The first through-hole contact portion 602 is electrically connected with the bottom of the light-emitting mesa 601 and passes through the first insulating layer 611A. The first through-hole contact portion 602 is used for hybrid bonding with the second through-hole contact portion 603, and thus electrically connects the bottom of the light-emitting mesa 601, particularly the second epitaxial layer 601C to the second electrode 610 (herein it is the anode). The first through-hole contact portion 602 is preferably a cylindrical through-hole, and the inner wall and/or central space is filled with a conductor, such as metallic copper. The diameter of the first through-hole contact portion 602 is of 0.3 to 2 μm, preferably 0.6 to 1.4 μm. The first through-hole contact portion 602 may be planarized at interface A (e.g., through chemical mechanical polishing CMP) to facilitate hybrid bonding with the second through-hole contact portion 603. Furthermore, in order to enhance the bonding strength and improve the conductivity between the first through-hole contact portion 602 and the second through-hole contact portion 603, a first interface metal layer may be arranged at the first aperture of the first through-hole contact portion 602, and the area of the first interface metal layer is greater than the area of the first aperture. Similarly, a second interface metal layer may be arranged at the second aperture of the second through-hole contact portion, and the area of the second interface metal layer is greater than the area of the second aperture. The areas of the first interface metal layer and the second interface metal layer may be equal, or the area of the first interface metal layer may be greater or less than the area of the second interface metal layer. After the first interface metal layer and the second interface metal layer are bonded to each other, the formed bonding surface is greater than the bonding surface formed by directly bonding the first aperture of the first through-hole contact portion 602 and the second aperture of the second through-hole contact portion 603, and thus the bonding strength is enhanced and the conductivity between the first through-hole contact portion 602 and the second through-hole contact portion 603 is improved. The first interface metal layer and the second interface metal layer are made of, for example, a conductive metal such as copper. Their formation methods may include, for example, physical vapor deposition (PVD), chemical vapor deposition (CVD), electroplating, chemical plating, and so on. The formation method of the first through-hole contact portion 602 may be, for example, as follows: a light-emitting mesa 601 and a first insulating layer 611A are formed on a temporary substrate, then the first insulating layer 611A is etched to form through-holes leading to the bottom of the light-emitting mesa 601, subsequently, a metal is deposited in the through-holes, and finally the apertures of the through-holes are planarized to form the bonding surface.

Furthermore, the first through-hole contact portion 602 is used to electrically connect the drive backplane 606 with the bottom (herein is the reflective mirror layer 615) of the epitaxial layer 601 (or light-emitting mesa) of the micro-LED array after bonding with the second through-hole contact portion 603, thereby connecting the epitaxial layer 601 to the anode 610. Herein, a first metal barrier layer 617 is arranged between the first through-hole contact portion 602 and the reflective mirror layer 615. The first metal barrier layer 617 can prevent the metal in the first through-hole contact portion 602 from diffusing into the epitaxial layer 601 or the first insulating layer 611A through the reflective mirror layer 615 and other layers (e.g., the bottom transparent conductive layer) that may be arranged therebetween, or from oxidizing. If the metal in the first through-hole contact portion 602 diffuses into the epitaxial layer 601, then the luminous performance of the epitaxial layer 601 will be affected; if it diffuses into the first insulating layer 611A, then the insulating effect of the first insulating layer 611A will be affected, thereby leading to leakage current or even short circuits; if the metal in the first through-hole contact portion 602 oxidizes, then it may cause poor contact between the first through-hole contact portion 602 and the reflective mirror layer 615, or even result in an open circuit in the electrical lines to the epitaxial layer 601. From this, it can be seen that by arranging the first through-hole contact portion 602 according to the present disclosure, metal diffusion in the first through-hole contact portion 602 can be effectively avoided, and thus risks such as reduced luminous performance, short circuit, and open circuit, etc. of the micro-LED can be effectively prevented. The combination of the first metal barrier layer 617 and the first barrier layer 203 and the second barrier layer 204 of the reflective mirror layer can further enhance the metal barrier and antioxidant effects.

The second electrode 610, herein is the anode, and is electrically connected with the drive backplane 606 through a third through-hole contact portion 614 passing through the first insulation layer 611A and the second insulation layer 611B. The anode 610 may be, for example, connected to an external power source or control source for supplying power for the micro-LED chip 600 or controlling the micro-LED chip 600. Herein, the third through-hole contact portion 614 may include a plurality of through-hole contact portions for connecting the second epitaxial layers 601C of a plurality of light-emitting mesas to the anode 610. Herein, it is exemplarily shown that the third through-hole contact portion 614 includes two through-hole contact portions, but this is merely an example, and other numbers of through-hole contact portions 614 are also conceivable. The third through-hole contact portion 614 may be formed either before hybrid bonding or after hybrid bonding. If the third through-hole contact portion 614 is formed before hybrid bonding, then the upper and lower portions of the third through-hole contact portion 614 are first formed in the upper stacked layer 600A and the lower stacked layer 600B, respectively, then after hybrid bonding, these two portions are interconnected to form the third through-hole contact portion, and then the first insulating layer 611A is etched from above to form the anode 610 on the third through-hole contact portion 614. If the third through-hole contact portion 614 is formed after hybrid bonding, then the first insulating layer 611A is etched from above to form through-holes leading to the drive backplane 606, metal is then deposited in the through-holes, then the third through-hole contact portion 614 is etched to form a recess, metal is then deposited in the recess to form the anode 610. The anode 610 and its connecting components may be made of materials such as metals (e.g., copper, silver, or aluminum), graphene, ITO, aluminum doped zinc oxide (AZO), or fluorine doped tin oxide (FTO), or any combination of the above materials.

The first bonding mark 609A is arranged in the first insulating layer 611A and exposes the first marking surface, i.e., the aperture of the first bonding mark. The function of the first bonding mark 609A in the upper stacked layer 600A is to serve as a mark aligned with the second bonding mark 609B in the lower stacked layer 600B, and thus precise hybrid bonding is achieved, the second bonding mark 609B is arranged in the second insulating layer 611B and exposes the second marking surface, i.e., the aperture of the second bonding mark. The alignment method of the first bonding mark 609A with the second bonding mark 609B is to align and adhere the first marking surface with the second marking surface during hybrid bonding, at this time, the upper stacked layer 600A and the lower stacked layer 600B have been aligned, and then hybrid bonding can be performed. The first bonding mark 609A and the second bonding mark 609B may be metal through-holes, and the two may be bonded at the interface. Furthermore, the first bonding mark 609A and the second bonding mark 609B may have enlarged apertures and/or the apertures may be coated with a metal layer to facilitate identification of their positions and enhance bonding strength.

The microlens 605 is arranged above the light-emitting mesa 601 for shaping such as focusing or collimating the light emitted therefrom. The microlens 605 includes a lens portion 605A and a spacer portion 605B. The lens portion 605A is arranged at the outermost side, i.e., the topmost and configured to shape light from the light-emitting mesa 601. The spacer portion 605B is arranged between the lens portion 605A and the light-emitting mesa 601 to adjust the focal position of the lens portion 605A, for example, parameters such as the thickness of the spacer portion 605B and the curvature of the lens portion 605A, etc., are adjusted, such that the focal point of the lens portion 605A is precisely located in the light-emitting mesa 601 of the micro-LED. The width of the microlens 605 is, for example, 0.8 to 4 μm, preferably 1 to 3 μm. The distance between the lens portion 605A and the cathode 604 is, for example, 0.05 to 4 μm, preferably 0.1 to 0.3 μm. The microlens 605 corresponds one-to-one with the light-emitting mesa 601. Meanwhile, in the present embodiment, adjacent microlenses 605 have gaps between them and their bottoms are connected with each other. The bottoms of the gaps are higher than the top of the light-emitting mesa 601 or higher than the bottom of the light-emitting layer 601B of the light-emitting mesa 601, and the lens portion 605A is located above the cathode 604. The microlens 605 may be formed through a plurality of deposition steps, and during the formation process of the microlens, a SiO₂ film layer is first deposited, then ion etching is performed, and the microlens is formed at positions on the surface of the top transparent conductive layer 608 corresponding to each light-emitting mesa 601.

The lower stacked layer 600B includes a second insulating layer 611B, a second through-hole contact portion 603, a drive backplane 606, and a second bonding mark 609B. The various components are described below, respectively.

The second insulating layer 611B is arranged on the drive backplane 606 and is configured to accommodate the second through-hole contact portion 603. The material of the second insulating layer 611B may be, for example, silicon dioxide, silicon nitride, high-k dielectric materials (e.g., hafnium oxide, aluminum oxide, etc.), and so on. The second insulating layer 611B may be, for example, formed on the drive backplane 606 through methods such as thermal oxidation or chemical vapor deposition (CVD), etc. The thickness of the second insulating layer 611B may be, for example, 1 to 3 μm, preferably 2 μm, and more preferably 0.6 to 1.4 μm. Furthermore, the second insulating layer 611B may be planarized at interface A (e.g., through chemical mechanical polishing CMP) to facilitate hybrid bonding with the first insulating layer 611A.

The second insulating layer 611B is transparent to light emitted from the light-emitting mesa 601. In some embodiments, the second insulating layer 611B is made of a dielectric material such as solid inorganic material or plastic material. In some embodiments, the solid inorganic material includes silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof. In some embodiments, the plastic material includes polymers such as SU-8, PermiNex, or benzocyclobutene (BCB), or transparent plastics (resins) including spin-on glass (SOG), or adhesive micro resist BCL-1200, or any combination thereof. In some embodiments, the second insulating layer 611B may facilitate the passage of light emitted from the light-emitting mesa 601. In some embodiments, the second insulating layer 611B may include a plurality of portions, such as three embedded dielectric portions and two adhering dielectric portions. The embedded dielectric portions refer to the dielectric layers surrounding each light emitting diode structure; while the adhering dielectric portions refer to the dielectric layers between two light emitting diode structures. The embedded dielectric portions and the adhering dielectric portions may have the same or different compositions.

The second through-hole contact portion 603, which passes through the second insulating layer 611B. The second through-hole contact portion 603 is configured to hybrid bond with the first through-hole contact portion 602 at interface A, and thus electrically connect the bottom of the light-emitting mesa 601, particularly the second epitaxial layer 601C to the second electrode 610 (herein it is the anode). The second through-hole contact portion 603 is preferably a cylindrical through-hole, and the inner wall and/or central space is filled with a conductor, such as metallic copper. The diameter of the second through-hole contact portion 603 is of 0.5 to 2.2 μm, preferably 0.8 to 1.6 μm. The second through-hole contact portion 603 may be planarized at interface A (e.g., through chemical mechanical polishing CMP) to facilitate hybrid bonding with the first through-hole contact portion 602. Furthermore, in order to enhance the bonding strength and improve the conductivity between the second through-hole contact portion 603 and the first through-hole contact portion 602, a second interface metal layer may be arranged at the second aperture of the second through-hole contact portion 603, and the area of the second interface metal layer is greater than the area of the second aperture. Similarly, a first interface metal layer may be arranged at the first aperture of the first through-hole contact portion 602, and the area of the first interface metal layer is greater than the area of the first aperture. The areas of the first interface metal layer and the second interface metal layer may be equal, or the area of the first interface metal layer may be greater or less than the area of the second interface metal layer. After the first interface metal layer and the second interface metal layer are bonded to each other, the formed bonding surface is greater than the bonding surface formed by directly bonding the first aperture of the first through-hole contact portion 602 and the second aperture of the second through-hole contact portion 603, and thus the bonding strength is enhanced and the conductivity between the first through-hole contact portion 602 and the second through-hole contact portion 603 is improved. The first interface metal layer and the second interface metal layer are made of, for example, a conductive metal such as copper. Their formation methods may include, for example, physical vapor deposition (PVD), chemical vapor deposition (CVD), electroplating, chemical plating, and so on. The formation method of the second through-hole contact portion 603 may be, for example, as follows: a drive backplane 606 is provided, then a second insulating layer 611B is formed on the drive backplane 606, then the second insulating layer 611B is etched to form through-holes leading to the top of the drive backplane 606, subsequently, a metal is deposited in the through-holes, and finally the apertures of the through-holes are planarized to form the bonding surface.

Furthermore, the second through-hole contact portion 603 is used to electrically connect the drive backplane 606 with the bottom (herein is the reflective mirror layer 615) of the epitaxial layer 601 (or light-emitting mesa) of the micro-LED array after bonding with the first through-hole contact portion 602, thereby connecting the epitaxial layer 601 to the anode 610. Herein, a first metal barrier layer 617 is arranged between the second through-hole contact portion 603 and the drive backplane 606. The first metal barrier layer 617 can prevent the metal in the second through-hole contact portion 603 from diffusing into the drive backplane 606 or the insulating layer 611B, or from oxidizing. If the metal in the second through-hole contact portion 603 diffuses into the drive backplane 606, then the electrical performance of the drive circuit will be affected, such as it causes a short circuit; if it diffuses into the insulating layer 611B, then the insulating effect of the insulating layer 611B will be affected, thereby leading to leakage current or even short circuits; if the metal in the second through-hole contact portion 603 oxidizes, then it may cause poor contact between the second through-hole contact portion 603 and the drive backplane 606, or even result in an open circuit in the electrical lines to the drive backplane 606. From this, it can be seen that by arranging the second through-hole contact portion 603 according to the present disclosure, metal diffusion in the second through-hole contact portion 603 can be effectively avoided, and thus risks such as short circuits or open circuits, etc. in the drive backplane 606 are effectively prevented. The combination of the first metal barrier layer 617 and the first barrier layer 203 and the second barrier layer 204 of the reflective mirror layer can further enhance the metal barrier and antioxidant effects.

The drive backplane 606 is electrically connected with the second through-hole contact portion 603 to electrically connect the second epitaxial layer 601C of the light-emitting mesa 601 to the anode 610. For this purpose, the drive backplane 606 has conductive line layers for interconnecting each second through-hole contact portion 603 to the corresponding anode 610. The drive backplane 606 may be, for example, a thin-film transistor TFT drive circuit and may include 2T1C drive circuit, 3T1C drive circuit, and 5T2C drive circuit. The drive backplane 606 is configured to drive the micro-LEDs, such as controlling the switching on/off and brightness of the micro-LEDs. The drive backplane 606 may include, for example, transistors, capacitors, a conductive line layer, an insulating layer, and a metal layer, etc. The conductive line layer is formed on the substrate and configured to supply power to the micro-LED array. The insulating layer is formed on the conductive line layer, through-holes are arranged in the insulating layer, and through-hole contact portions (e.g., IC copper pillars) are arranged in the through-holes for electrically connecting the conductive line layer with the micro-LED array. The metal layer is used for bonding and electrically contacting the micro-LEDs. The conductive line layer, the metal layer, and the insulating layer may be formed on substrate through deposition methods such as physical vapor deposition (PVD) and chemical vapor deposition (CVD).

The second bonding mark 609B is arranged in the second insulating layer 611B and exposes the second marking surface, i.e., the aperture of the second bonding mark. The function of the second bonding mark 609B in the lower stacked layer 600B is to serve as a mark aligned with the first bonding mark 609A in the upper stacked layer 600A, and thus precise hybrid bonding is achieved. The alignment method of the first bonding mark 609A with the second bonding mark 609B is to align and adhere the first marking surface with the second marking surface during hybrid bonding, at this time, the upper stacked layer 600A and the lower stacked layer 600B have been aligned, and then hybrid bonding can be performed. The first bonding mark 609A and the second bonding mark 609B may be metal through-holes, and the two may be bonded at the interface. Furthermore, the first bonding mark 609A and the second bonding mark 609B may have enlarged apertures and/or the apertures may be coated with a metal layer to facilitate identification of their positions and enhance bonding strength.

After the formation of the lower stacked layer 600B and the upper stacked layer 600A, the lower stacked layer 600B is joined with the upper stacked layer 600A through hybrid bonding, such that the first through-hole contact portion 602 is bonded with the second through-hole contact portion 603 and the first insulating layer 611A is bonded with the second insulating layer 611B, optionally the first bonding mark 609A is bonded with the second bonding mark 609B, and the upper and lower portions of the third through-hole contact portion 614 are bonded with each other. The present disclosure solves the technical problem encountered in manufacturing upside-down arranged trapezoidal light-emitting mesa with a large upper surface and a small lower surface, i.e., the problem of electrical connection of the light-emitting mesa to the driving circuit, by respectively fabricating the upper stacked layer 600A and the lower stacked layer 600B and then joining them with each other through hybrid bonding. The present disclosure achieves electrical connection of the light-emitting mesa 601 to the drive backplane 606 through hybrid bonding, allowing both the upper stacked layer 600A and the lower stacked layer 600B to be manufactured from the surface opposed to the hybrid bonding surface, i.e., interface A, towards the hybrid bonding surface, so that high-quality conductive structures, such as the first to third through-hole contact portions (such as IC copper pillars) are achieved, and the length of the conductive structure can also be flexibly selected.

An exemplary of the hybrid bonding may include the following two parts:

(1) Dielectric-to-dielectric bonding (i.e., bonding between the first insulating layer 611A and the second insulating layer 611B): at room temperature, extremely flat and smooth dielectric surfaces obtained through chemical mechanical polishing (CMP) are brought into close contact at room temperature after activation through methods such as plasma treatment to achieve preliminary bonding.

(2) Metal-to-metal bonding (i.e., bonding between through-hole contact portions): after completing the dielectric-to-dielectric bonding, the upper and lower stacked layers are heated to 200-400°C for annealing treatment to strengthen the dielectric bonding and facilitate metal-to-metal bonding, thereby achieving hybrid bonding.

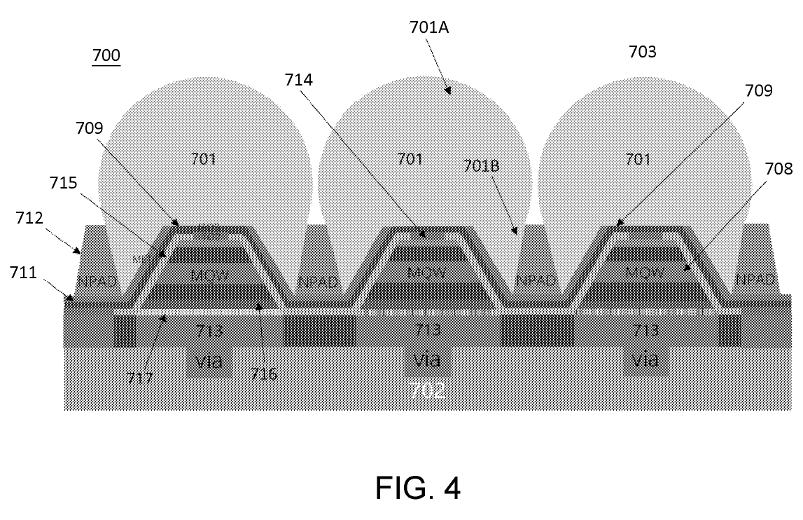

FIG. 4 illustrates a second application scenario of the reflective mirror layer according to the disclosure.

The structure of the micro-LED chip 700 in the second application scenario shown in FIG. 4 is substantially the same as the micro-LED chip 600 in the first application scenario shown in FIG. 3, and the primary difference lies in that, in the second application scenario, the light-emitting mesa 708 (or epitaxial layer) of the micro-LED chip 700 is a normally arranged trapezoidal structure with a small upper surface and a large lower surface. Herein, the reflective mirror layer 717 according to the present disclosure is arranged only between the bottom transparent conductive layer 716 and the anode 713, and is not arranged on the side surface of the light-emitting mesa 708.

The various components of the micro-LED chip 700 are described in detail below.

A drive circuit 702 (i.e., drive backplane), drive circuit 702 may be silicon-based or glass-based, i.e., the drive circuit 702 may have a silicon or glass substrate. The drive circuit 702 may be various forms of drive circuits, such as CMOS drive circuits or thin-film transistor TFT drive circuits, such as 2T1C drive circuit, 3T1C drive circuit, and 5T2C drive circuit. The drive circuit 702 is configured to drive the micro-LEDs, such as controlling the switching on/off and brightness of the micro-LEDs. The drive circuit 702 may include, for example, transistors, capacitors, a conductive line layer, an insulating layer, and a metal layer. The conductive line layer is formed on the substrate and configured to supply power to the micro-LED array. The insulating layer is formed on the conductive line layer, through-holes are arranged in the insulating layer, and through-hole contact portions (e.g., IC copper pillars) are arranged in the through-holes for electrically connecting the conductive line layer with the micro-LED array. The metal layer is used for bonding and electrically contacting the micro-LEDs. The conductive line layer, the metal layer, and the insulating layer may be formed on substrate through deposition methods such as physical vapor deposition (PVD) and chemical vapor deposition (CVD). According to specific application scenarios, the metal layer and the insulating layer may be patterned through photolithography and form through-holes on them. Furthermore, transistors and capacitors in the conductive circuit layer may be formed through deposition and etching.

In one embodiment of the present disclosure, the drive circuit may be electrically connected with each micro-LED in the micro-LED array through individual metal interconnections. In some embodiments, each micro-LED may be individually electrically controlled by the drive circuit. In some embodiments, the drive circuit may be electrically connected with electrodes of the micro-LED chips through metal interconnections. In some embodiments, a dielectric layer may be formed in the gaps between the micro-LEDs. In some embodiments, the dielectric layer may also be formed in the gaps between the interconnections.

The micro-LED chip includes a plurality of micro-LED arrays, and each micro-LED array includes a plurality of micro-LEDs. The drive method of the micro-LEDs is, for example, a passive matrix (PM) drive, the cathodes of all micro-LEDs of each array are connected to a cathode together, while micro-LEDs of the same number of each array are connected to corresponding anodes, respectively. Thus, the on/off and brightness of each LED can be individually controlled by controlling the model on the corresponding cathode and anode.

A micro-LED array 703, which includes a light-emitting mesa 708. The micro-LED array 703 is formed on the drive circuit 702. For the specific structure of the light-emitting mesa, reference may be made to the description below. The micro-LED array 703 is joined with the drive circuit 702 through bonding, and the bonding methods include full surface bonding and hybrid bonding. In some embodiments, the micro-LED array may include blue micro-LEDs. In some embodiments, the pitch of the micro-LED array, i.e., the minimum center-to-center distance between micro-LEDs, may be between approximately 2 micrometers to approximately 50 micrometers. In some embodiments, the number of pixels on the micro-LED chip 100 may be between thousands to millions.

Each micro-LED includes the following components:

The light-emitting mesa 708, which is configured to emit light, the area of the upper surface of the light-emitting mesa 708 is less than the area of the lower surface, i.e., it is a normally arranged trapezoid shape. The light-emitting mesa 708 includes a first epitaxial layer, a second epitaxial layer, and a light-emitting layer arranged between the first epitaxial layer and the second epitaxial layer. The light-emitting mesa 708 includes a first epitaxial layer, a light-emitting layer, and a second epitaxial layer deposited in sequence, the light-emitting layer includes a multi-quantum-well layer and an electron barrier layer. In one embodiment of the present disclosure, the first epitaxial layer is an N-type GaN layer or an N-type AlGaN layer, the second epitaxial layer is a P-type GaN layer or a P-type AlGaN layer, i.e., the material of the second epitaxial layer may be a material layer of a second conductivity type including at least two or more elements of Ga, N, As, Al, In, and P, and the first epitaxial layer may be a material layer of a first conductivity type including at least two or more elements of Ga, N, As, Al, In, and P. The types of the first epitaxial layer and the second epitaxial layer may be interchanged. The multi-quantum-well layer includes an InGaN/GaN multi-quantum-well layer, an InGaN/AlGaN multi-quantum-well layer, or an InGaAs/AlGaAs multi-quantum-well layer. The electron barrier layer is arranged on the first side of the light-emitting layer, and the first side refers to the side along which electrons migrate out of the light-emitting layer. In yet another embodiment of the present disclosure, the first epitaxial layer may also be a P-type GaN layer or a P-type AlGaN layer, and the second epitaxial layer is an N-type GaN layer or an N-type AlGaN layer.

In one embodiment of the present disclosure, the first epitaxial layer (or the first type epitaxial layer) is a semiconductor material with a first conductivity type and includes a plurality of semiconductor layers. The main matrix material may be, but is not limited to, materials such as Ga, N, As, P, In, or Al, etc. Furthermore, the first epitaxial layer may include, from top to bottom, but is not limited to, a waveguide layer, a confinement layer, a transition layer, and a window layer; furthermore, an ohmic contact layer may be formed below the window layer. In some embodiments, the second epitaxial layer (or simply referred to as the second type epitaxial layer) is a semiconductor material with a second conductivity type and includes a plurality of semiconductor layers. The main matrix material of the second epitaxial layer may be, but is not limited to, two or more materials such as Ga, N, As, P, In, or Al, etc. Furthermore, the second epitaxial layer may include, from top to bottom, but is not limited to, a confinement layer and a waveguide layer; furthermore, in some embodiments, an ohmic contact layer may be formed on the confinement layer. In one embodiment, the first epitaxial layer is an N-type GaN layer or an N-type AlGaN layer, and the second epitaxial layer is a P-type GaN layer or a P-type AlGaN layer, i.e. the material of the second epitaxial layer is a material layer of a second conductivity type including at least two or more elements of Ga, N, As, Al, In, and P, and the first epitaxial layer is a material layer of a first conductivity type including at least two or more elements of Ga, N, As, Al, In, and P. In another embodiment, the first epitaxial layer may also be a P-type GaN layer or a P-type AlGaN layer, and the second epitaxial layer is an N-type GaN layer or an N-type AlGaN layer. In embodiments of the present disclosure, the light-emitting mesa is a step shape or a trapezoid shape.

The first electrode, herein, is the cathode 711, which is electrically connected with the first epitaxial layer of the light-emitting mesa 708 through the top transparent conductive layer 709 and the cathode contact portion 714 passing through the passivation layer 715. The cathode 711 may further include a ring-shaped reflective electrode 712 arranged around the light-emitting mesa 708, the reflective electrode may be formed, for example, by magnetron sputtering or evaporation, and its material may use, for example, Al or Al alloy metals as the sidewall reflective mirror surface, and electrode stacked layer metal may be metallic materials such as Ni, Al, Ti, Ni, Pt, Au, etc. The passivation layer 715 is arranged between the top transparent conductive layer 709 and the light-emitting mesa 708, its function is not only to reduce current leakage at the sidewalls, but also to passivate sidewall defects and block damage to the light-emitting mesa caused by water, oxygen, etc., during operation. The passivation layer 715 may be formed by depositing SiO₂ material using a CVD process, and also may be formed by depositing Al₂O₃ material using an ALD process. The cathode 711 may be, for example, a common cathode structure, i.e., an array of micro-LEDs is connected to a common cathode.

The second electrode, herein is the anode 713, which is arranged at the bottom of the light-emitting mesa 708 to supply power to the anode 713. The anode 713 of micro-LED in the array can be optionally connected to signal contact portions (not shown). The connection method of a common cathode and an optional anode can form a passive matrix control mode to control the on/off and brightness adjustment of each micro-LED. On the light-emitting mesa 708 and the anode 713, additional layers, such as a passivation layer 615, a top transparent conductive layer 709, a cathode 711, etc., are also provided. It should be noted that in other embodiments, the polarities of the first electrode and the second electrode may be interchanged, i.e., the cathode 711 and the anode 713 may be interchanged.

The bottom transparent conductive layer 716, which is arranged between the bottom of the light-emitting mesa 708 and the reflective mirror layer 717. The bottom transparent conductive layer 716 is configured to electrically connect the second epitaxial layer of the light-emitting mesa 708 to the reflective mirror layer 717 and further electrically connect it to the anode 713. The material of the bottom transparent conductive layer 716 may be, for example, a metal oxide such as indium tin oxide ITO or zinc oxide ZnO, etc., its formation methods may include, for example, physical vapor deposition (PVD), chemical vapor deposition (CVD), sol-gel method, solution coating method, etc.

The reflective mirror layer 717, which is arranged at the bottom of the light-emitting mesa 708 and covers the bottom transparent conductive layer 716. The reflective mirror layer 717 is configured to reflect, together with the bottom anode 713, light from the light-emitting mesa 708 upward to the top emitting light. Furthermore, the reflective mirror layer 717 is also configured to electrically connect the bottom transparent conductive layer 716 with the anode 713. A side of the reflective mirror layer 717 facing the light-emitting mesa 708 has an atomic layer deposition layer. The atomic layer deposition layer can block metal from the reflective metal layer to prevent its diffusion without substantially affecting light reflection, such as prevent it from diffusing through the bottom transparent conductive layer 716 into the light-emitting mesa 708 to affect the light-emitting efficiency of the light-emitting mesa 708. For the specific structure of the reflective mirror layer 717, reference may be made to FIGS. 1 and 2 and their descriptions.

The reflective mirror layer 717 includes, from top to bottom (i.e., from the side facing the light-emitting mesa 708 to the side facing away from the light-emitting mesa 708) an atomic layer deposition layer 201, a reflective metal layer 202, a first barrier layer 203, and a second barrier layer 204, the upper side of the reflective mirror layer 200 faces the light-emitting mesa or epitaxial layer of the micro-LED, and the lower side of the reflective mirror layer 200 faces away from the light-emitting mesa or epitaxial layer of the micro-LED or faces the bottom transparent conductive layer.

For example, the stacked layer structure of the reflective mirror layer 717 is as follows (in an order from close to the light-emitting mesa to far away from the light-emitting mesa): Atomic layer deposition layer 201, the material of which is nickel, the thickness is 5 angstroms; Reflective metal layer 202, the material of which is silver, the thickness is 1000 angstroms; First and second barrier sublayers 203A and 203B, the materials are titanium and platinum, respectively, the thicknesses are 200 and 500 angstroms, respectively; Second barrier layer 204, the material of which is titanium, the thickness is 200 angstroms.

Furthermore, the number of the first barrier layer 203 is 3.

The reflective mirror layer 717 can be formed, for example, through methods such as evaporation, sputtering, or chemical vapor deposition (CVD), etc., the atomic layer deposition layer 201 of the reflective mirror layer 717 is formed by atomic layer deposition.

A microlens 701, which is arranged above the light-emitting mesa 708 for shaping such as focusing or collimating the light emitted therefrom. The microlens includes a lens portion 701A and a spacer portion 701B. The lens portion 701A is arranged at the outermost side, i.e., the topmost and configured to shape light from the light-emitting mesa 708. The spacer portion 701B is arranged between the lens portion 701A and the light-emitting mesa 708 to adjust the focal position of the lens portion 701A, for example, parameters such as the thickness of the spacer portion 701B and the curvature of the lens portion 701A, etc. are adjusted, such that the focal point of the lens portion 701A is precisely located in the light-emitting mesa 708 of the micro-LED. The microlens 701 corresponds one-to-one with the light-emitting mesa 708. Meanwhile, in the present embodiment, adjacent microlenses 701 have gaps between them and their bottoms are connected with each other. The bottoms of the gaps are higher than the top of the light-emitting mesa 701 and higher than the bottom of the light-emitting mesa 708, and the lens portion 701A is located above the cathode 711. The microlens 701 may be formed through a plurality of deposition steps, and during the formation process of the microlens, a SiO₂ film layer is first deposited, then ion etching is performed, and the microlens is formed at positions on the surface of the transparent conductive layer 709 corresponding to each light-emitting mesa 708.

The microlens may be made of various materials transparent at the wavelength emitted by a single micro-LED pixel. Examples of transparent materials used for the microlens include polymers, dielectrics, and semiconductors. In some embodiments, dielectric materials include one or more materials such as silicon oxide, silicon nitride, silicon carbide, titanium oxide, zirconium oxide, aluminum oxide, etc. In some embodiments, the microlens is made of photoresist. In some embodiments, the shape of the microlens is typically a hemispherical shape. In some embodiments, the central axis of the microlens aligns with or is the same as the central axis of the individual micro-LED pixel without a lens. It should be understood that a complete display panel includes an array of numerous individual pixels and many microlenses. Furthermore, the relationship between the microlens and the pixel light source is not necessarily one-to-one correspondence, and the relationship between the drive circuit (not shown) and the pixel light source also is not necessarily one-to-one. The pixel light source may also include a plurality of individual light-emitting elements, such as individual pixel LEDs connected in parallel. In some embodiments, a single microlens may cover a plurality of individual LED pixels without lenses. A single microlens has positive focal power, and its position can reduce the divergence or viewing angle of the light emitted by the corresponding pixel light source. For example, the light beam emitted by the pixel light source originally has a relatively wide divergence angle. In one embodiment, the initial angle of the beam edge rays relative to a vertical axis perpendicular to the substrate is greater than 60°. After being refracted by a microlens, the divergence angle of the new edge rays is reduced. In one embodiment, the reduced angle is less than 30°. The microlenses in a microlens array are usually the same. Examples of microlenses include spherical microlenses, non-spherical microlenses, Fresnel microlenses, and cylindrical microlenses.

The size of each micro-LED chip does not exceed 1 centimeter, preferably not exceeding 20 micrometers. The micro-LED structures are formed in the form of an array in the micro-LED chip, and resolutions such as 720*480, 640*480, 1920*1080, 1280*720, 2K, or 4K. The diameters of the micro-LED structures are in the nanometer-level, for example, 20 nm to 100 nm.

In some embodiments of the present disclosure, the micro-LED array may include a single layer of micro-LED structures. In some embodiments of the present disclosure, the micro-LED array may include multiple layers of vertically stacked micro-LED structures.

In some embodiments of the present disclosure, the micro-LED array may include blue micro-LEDs. In some embodiments of the present disclosure, the pitch of the micro-LED array, i.e., the minimum center-to-center distance between micro-LEDs, may be between approximately 2 micrometers and approximately 50 micrometers. In some embodiments, the number of pixels on the micro-LED chip may be between thousands to millions.

Although some embodiments of the present disclosure have been described in the present application, however, those skilled in the art will appreciate that these embodiments are merely illustrated as examples. Numerous variation schemes, alternative schemes, and improvement schemes may be conceived by those skilled in the art in light of the teachings of the present disclosure without departing from the scope of the present disclosure. The appended claims are intended to define the scope of the present disclosure and thus encompass methods and structures within the scope of these claims themselves and their equivalent variations.

What is claimed is:

1. A micro-LED, comprising:
a light-emitting mesa configured to emit light; and
a reflective mirror layer configured to reflect the light from the light-emitting mesa, wherein a side of the reflective mirror layer facing the light-emitting mesa has an atomic layer deposition layer.

2. The micro-LED according to claim 1, wherein an upper surface of the light-emitting mesa is greater than a lower surface of the light-emitting mesa, and the reflective mirror layer comprises:
a side reflective mirror layer covering at least a part of a side surface of the light-emitting mesa, and a side of the side reflective mirror layer facing the light-emitting mesa has an inclined surface to reflect the light from the light-emitting mesa upward; and
a bottom reflective mirror layer covering at least a part of a bottom surface of the light-emitting mesa, wherein a side of the bottom reflective mirror layer facing the light-emitting mesa has an atomic layer deposition layer.

3. The micro-LED according to claim 1, wherein an upper surface of the light-emitting mesa is less than a lower surface of the light-emitting mesa, and the reflective mirror layer covers a bottom surface of the light-emitting mesa.

4. The micro-LED according to claim 2, wherein the reflective mirror layer comprises, starting from a side facing the light-emitting mesa:
an atomic layer deposition layer, a material of the atomic layer deposition layer is selected from one or more of the following items: nickel, platinum, titanium, and tantalum;
a reflective metal layer, the material of the reflective metal layer is selected from one or more of the following items: silver, aluminum, and gold;
a first barrier layer comprising at least a first barrier sublayer and a second barrier sublayer, wherein the materials of the first barrier sublayer and the second barrier sublayer are respectively selected from one or more of the following items: platinum, titanium, and tantalum; and
a second barrier layer, its material is selected from one or more of the following items: platinum, titanium, and tantalum.

5. The micro-LED according to claim 4, wherein the material of the second barrier layer is different from the material of the first barrier sublayer.

6. The micro-LED according to claim 4, wherein:
the material of the atomic layer deposition layer is nickel;
the material of the reflective metal layer is silver;
the materials of the first barrier sublayer and the second barrier sublayer are titanium and platinum, respectively; and
the material of the second barrier layer is titanium.

7. The micro-LED according to claim 5, wherein:
a thickness of the atomic layer deposition layer is 3 to 8 angstroms;
a thickness of the reflective metal layer is 800 to 1200 angstroms;
a thickness of the first barrier sublayer is 100 to 300 angstroms, and a thickness of the second barrier sublayer is 400 to 600 angstroms; and
a thickness of the second barrier layer is 100 to 300 angstroms.

8. The micro-LED according to claim 4, wherein the reflective mirror layer comprises N first barrier sublayers and N second barrier sublayers arranged alternately with each other, wherein N is an integer and N = 2 to 5.

9. The micro-LED according to claim 4, further comprising:
an insulating layer comprising a recess, at least a part of the light-emitting mesa is arranged within the recess.

10. The micro-LED according to claim 9, further comprising:
a passivation layer arranged between the reflective mirror layer and the insulating layer.

11. The micro-LED according to claim 9, wherein the light-emitting mesa comprises:
a first epitaxial layer extending beyond the recess of the insulating layer;
a second epitaxial layer located in the recess and in electrical contact with a first through-hole contact portion;
a light-emitting layer located in the recess and between the first epitaxial layer and the second epitaxial layer, and in electrical contact with the first epitaxial layer and the second epitaxial layer.

12. The micro-LED according to claim 1, further comprising:
a through-hole contact portion located at a bottom of the light-emitting mesa to electrically connect the light-emitting mesa with a drive circuit; and
an etch buffer layer located between the reflective mirror layer and the through-hole contact portion.

13. The micro-LED according to claim 12, further comprising:
a bottom transparent conductive layer located between the reflective mirror layer and the through-hole contact portion to electrically connect the light-emitting mesa with the through-hole contact portion.

14. A micro-LED chip, comprising:
a plurality of micro-LEDs according to claim 9, wherein the light-emitting mesa comprises a first epitaxial layer, a light-emitting layer, and a second epitaxial layer deposited in sequence, and each micro-LED further comprises:
a first electrode;
a passivation layer located between the side reflective mirror layer and the insulating layer;
a top transparent conductive layer located on the first epitaxial layer and in electrical contact with the first epitaxial layer; and
a second electrode located on a surface of the top transparent conductive layer; and
a drive circuit provided with a metal layer on its surface, the drive circuit is provided with a plurality of through-hole contact portions, and the plurality of through-hole contact portions are electrically connected with the metal layer, and the micro-LED is connected to the drive circuit through a bottom conductive bonding layer, and each light-emitting mesa corresponds to one of the plurality of through-hole contact portions.

15. The micro-LED chip according to claim 14, wherein the polarity of the second electrode is opposite to the polarity of the first electrode.

16. The micro-LED chip according to claim 14, wherein the material of the second epitaxial layer is a material layer of a second conductivity type comprising at least two or more elements of Ga, N, As, Al, In, and P, and the first epitaxial layer is a material layer of a first conductivity type comprising at least two or more elements of Ga, N, As, Al, In, and P, wherein the first conductivity type is different from the second conductivity type.

17. A micro-LED chip according to claim 14, wherein a first side of the light-emitting layer has an electron barrier layer, and the first side is a side along which electrons migrate out of the light-emitting layer.

18. The micro-LED chip according to claim 14, wherein the material of the passivation layer is a Si₃N₄ film, a SiO₂ film, or an Al₂O₃ film.

19. The micro-LED chip according to claim 14, further comprising a microlens, wherein the microlens comprises:
a lens portion located at an outermost side; and
a spacer portion located between the lens portion and the light-emitting mesa.

20. A micro-LED chip, comprising:
an upper stacked layer, which comprises:
a light-emitting mesa configured to emit light, wherein a top surface area of the light-emitting mesa is greater than a bottom surface area of the light-emitting mesa;
a first insulating layer configured to accommodate a light-emitting mesa;
a reflective mirror layer, wherein the reflective mirror layer covers at least a part of a side surface and/or at least a part of the bottom surface of the light-emitting mesa, and has an atomic layer deposition layer on a side facing the light-emitting mesa, and the atomic layer deposition layer is configured to block metal diffusion in the reflective mirror layer; and
a first through-hole contact portion electrically connected with the bottom surface of the light-emitting mesa and passing through the first insulating layer, wherein the first insulating layer further accommodates the first through-hole contact portion; and
a lower stacked layer, which comprises:
a second insulating layer; and
a second through-hole contact portion passing through the second insulating layer; and
a drive backplane electrically connected with the second through-hole contact portion, wherein the lower stacked layer is bonded with the upper stacked layer through hybrid bonding, such that the first through-hole contact portion is bonded with the second through-hole contact portion and the first insulating layer is bonded with the second insulating layer.
